(19) United States
(12) Patent Application Publication
(10) Pub. No.: US 2024/0170477 A1
(43) Pub. Date: May 23, 2024

(54) SEMICONDUCTOR INTEGRATED CIRCUIT DEVICE INCLUDING ELECTROSTATIC DISCHARGE PROTECTION CIRCUIT

(71) Applicant: SK hynix Inc., Gyeonggi-do (KR)

(72) Inventors: Chang Hwi LEE, Gyeonggi-do (KR); Ho Sang LEE, Gyeonggi-do (KR); Dong Ju LIM, Gyeonggi-do (KR)

(21) Appl. No.: 18/353,211

(22) Filed: Jul. 17, 2023

(30) Foreign Application Priority Data
Nov. 22, 2022 (KR) 10-2022-0157247

(51) Int. Cl. H01L 27/02; H10B 12/00

(52) U.S. Cl. CPC H01L 27/0255; H01L 27/0296; H10B 12/50

(57) ABSTRACT

A semiconductor integrated circuit device may include a first protecting unit and a second protecting unit. The first protecting unit may include first to nth backward diodes serially connected between a pad and a first power line. The second protecting unit may include at least one forward diode connected between the pad and a second power line. The first backward diode and the forward diode connected to the pad may be integrated in one conductive well without a severance to face each other.

The present application claims priority under 35 U.S.C. § 119(a) to Korean application number 10-2022-0157247, filed on Nov. 22, 2022, in the Korean Intellectual Property Office, which is incorporated herein by reference in its entirety.

### BACKGROUND

### 1. Technical Field

Various embodiments generally relate to a semiconductor integrated circuit device, more particularly, a semiconductor integrated circuit device including an electrostatic discharge protection circuit.

### 2. Related Art

In general, a semiconductor integrated circuit device may include an electrostatic discharge (ESD) protection circuit arranged between a pad for receiving an external voltage and an internal circuit to discharge a static electricity. When a voltage including the static electricity may be applied to the pad, the ESD protection circuit may be selectively turned-on to block an inflow of the static electricity into the internal circuit.

### SUMMARY

In various embodiments of the present disclosure, a semiconductor integrated circuit device may include a first protecting unit and a second protecting unit. The first protecting unit may include first to nth backward diodes serially connected between a pad and a first power line. The second protecting unit may include at least one forward diode connected between the pad and a second power line. The first backward diode and the forward diode connected to the pad may be integrated in one conductive well without a severance to face each other.

In various embodiments of the present disclosure, a semiconductor integrated circuit device may include a first forward diode a first backward diode. The first forward diode may include an anode and a cathode. The anode may be electrically connected between a pad and a power voltage terminal. The anode may include a P-well having a second depth in a first N-well having a first depth. The cathode may include an N-type impurity region having a high concentration formed in the P-well. The N-type impurity region may be connected to the pad. The first backward diode may include an anode and a cathode. The cathode may be electrically connected between the pad and a ground voltage terminal. The anode may include a second N-well in the P-well. The second N-well may have a third depth shallower than the second depth. The anode may include a P-type impurity region having a high concentration formed in the second N-well. The P-type impurity region may be connected to the pad. When a voltage including a static electricity may be inputted from the pad, a parasitic bipolar junction transistor (BJT) may be generated between the first N-well, the P-well and the second N-well.

According to various embodiments, when the static electricity may not be inputted from the pad, a parasitic capacitance of the ESD protection circuit may be reduced. In contrast, when the static electricity may be inputted from the pad, an on-resistance of the ESD protection circuit may be decreased.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a block diagram illustrating a semiconductor integrated circuit device in accordance with various embodiments;

FIG. 2 is a plan view illustrating a semiconductor memory device with an ESD protection circuit in accordance with various embodiments;

FIG. 3 is a cross-sectional view illustrating a semiconductor memory device with an ESD protection circuit in accordance with various embodiments;

FIG. 4 is a circuit diagram illustrating an ESD protection circuit in accordance with various embodiments;

FIG. 5A is a view illustrating a voltage level of each connection node in a first protecting unit in accordance with various embodiments;

FIG. 5B is a view illustrating a voltage level of each connection node in a second protecting unit in accordance with various embodiments;

FIG. 6 is a circuit diagram illustrating a parasitic capacitance of the ESD protection circuit in FIG. 4;

FIG. 7 is a circuit diagram illustrating a voltage distribution circuit of a semiconductor integrated circuit device in accordance with various embodiments;

FIG. 8 is a plan view illustrating an ESD protection circuit in accordance with various embodiments;

FIG. 9 is a circuit diagram illustrating an ESD protection circuit in accordance with various embodiments;

FIGS. 10A to 10D are plan views illustrating a method of manufacturing the ESD protection circuit in FIG. 9;

FIGS. 11A to 11D are cross-sectional views taken along a line A-A′ in FIGS. 10A to 10D;

FIG. 12A is a circuit diagram illustrating a parasitic path of an ESD protection circuit in accordance with various embodiments;

FIG. 12B is a plan view illustrating a parasitic path of an ESD protection circuit in accordance with various embodiments; and

FIG. 12C is a cross-sectional view illustrating a parasitic path of an ESD protection circuit in accordance with various embodiments.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the scope of the present invention.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and scope of the present invention.

Recently, as an integration degree of the semiconductor integrated circuit device has increased, a rapid input/output signal may be required. However, it may be difficult to rapidly input/output a signal due to a parasitic capacitance of the ESD protection circuit adjacent to the pad, particularly, an input/output pad. Further, a wave distortion of the input/output signal may be generated.

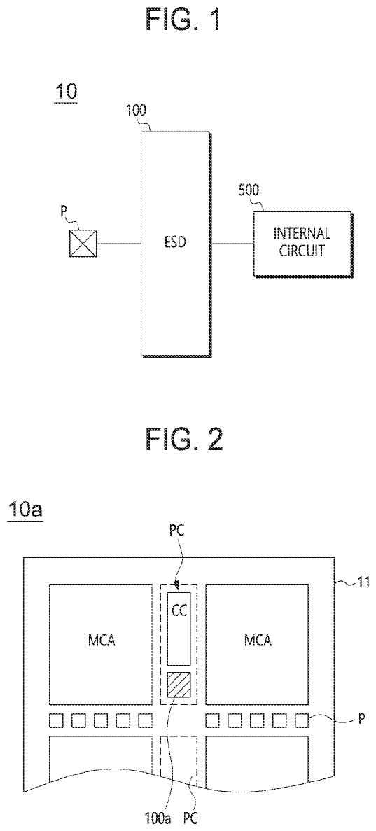

FIG. 1 is a block diagram illustrating a semiconductor integrated circuit device in accordance with various embodiments.

Referring to FIG. 1, a semiconductor integrated circuit device may include a pad P, an ESD protection circuit 100 and an internal circuit 500.

In this embodiment, the pad P may include an I/O pad configured to transmit and receive an I/O signal.

The ESD protection circuit 100 may be connected between the pad P and the internal circuit 500. When a positive static electricity exceeding in magnitude a critical value or a negative static electricity exceeding in magnitude a critical value may be inputted, the ESD protection circuit 100 may discharge the static electricity through a power voltage line.

The internal circuit 500 may include a memory circuit or a control circuit driven by power voltages, not limited thereto.

In contrast, when a pad voltage corresponding to normal I/O data without the static electricity may be inputted to the pad P, the pad voltage may be transmitted to the internal circuit 500, and not through the ESD protection circuit 100.

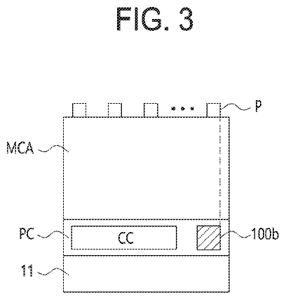

FIG. 2 is a plan view illustrating a semiconductor memory device with an ESD protection circuit in accordance with various embodiments and FIG. 3 is a cross-sectional view illustrating a semiconductor memory device with an ESD protection circuit in accordance with various embodiments.

Referring to FIGS. 2 and 3, a semiconductor memory device 10a and 10b as a semiconductor integrated circuit device may include a semiconductor substrate 11, a plurality of memory cell arrays MCA, a peripheral circuit PC including ESD protection circuits 100a and 100b, and a plurality of pads P.

For example, the semiconductor substrate 11 may include Si, Ge, SiGe, etc. Alternatively, the semiconductor substrate 11 may include a polysilicon substrate, a silicon-on-insulator (SOI) substrate, a germanium-on-insulator (GeOI) substrate, etc.

The memory cell arrays MCA may be arranged on the semiconductor substrate 11 in a matrix shape. For example, the memory cell arrays MCA may correspond to a bank of a dynamic random access memory DRAM device or a plane of a NAND device. The memory cell array MCA may include a plurality of memory cells arranged in a matrix shape. For example, the memory cell may include a volatile memory cell or a non-volatile memory cell. The memory cells may be arranged in a two-dimensional structure or a three-dimensional structure.

As shown in FIG. 2, the peripheral circuit PC may be arranged on the semiconductor substrate 11. The peripheral circuit PC may be parallel to the memory cell arrays MCA.

Alternatively, as shown in FIG. 3, the peripheral circuit PC may be interposed between the semiconductor substrate 11 and the memory cell array MCA. That is, the memory cell array MCA may be stacked on the peripheral circuit PC.

The peripheral circuit PC may include control circuits CC configured to control a selected memory cell of the memory cell array MCA together with the ESD protection circuits 100a and 100b. For example, the control circuits CC may include a row control circuit, a column control circuit, a sense amplifier, a page buffer, a control signal generation circuit, etc., not limited thereto.

Further, the peripheral circuit PC may correspond to the internal circuit 500 in FIG. 1. Alternatively, the peripheral circuit PC may be a part of the internal circuit 500 in FIG. 1.

In one embodiment, when the pad voltage including the static electricity is inputted from the pad P, the ESD protection circuit 100a or 100b directs the static electricity away from being conducted into the control circuits CC and the memory cell array MCA. In contrast, when the normal pad voltage is inputted, the pad voltage is transmitted to the internal circuit 500 without the operation of the ESD protection circuit 100a and 100b.

The pads P may be configured to receive various signals as well as the I/O data. As shown in FIG. 2, the pads P may be arranged on a horizontal surface along with the memory cell array MCA. Alternatively, as shown in FIG. 3, the pads P may be arranged on the memory cell array MCA.

The ESD protection circuit 100a or 100b may be electrically connected between the pad P and the memory cell array MCA or between the pad and the control circuit CC connected with the memory cell array MCA to prevent the inflow of the static electricity.

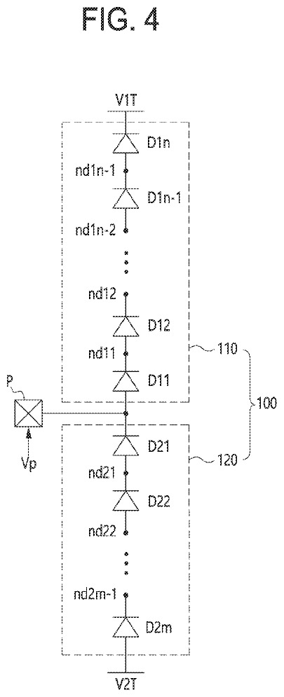

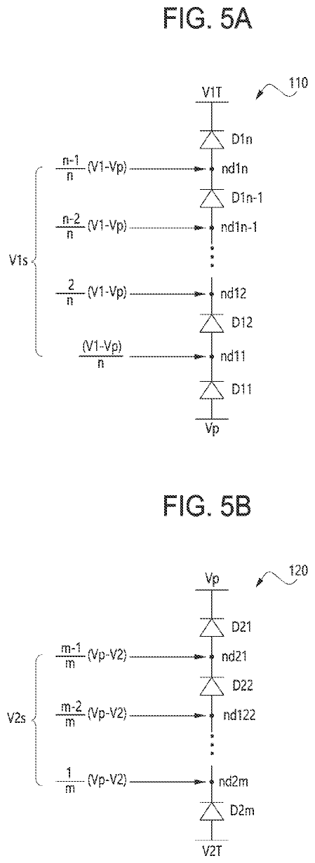

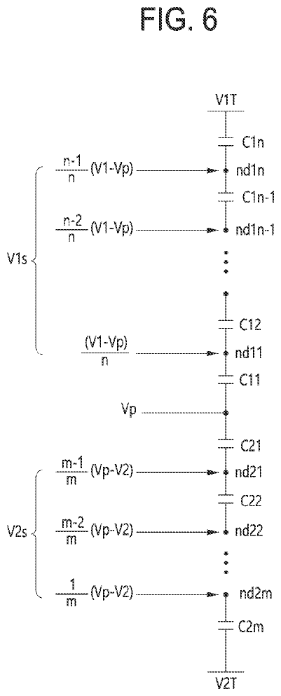

FIG. 4 is a circuit diagram illustrating an ESD protection circuit in accordance with various embodiments, FIG. 5A is a view illustrating a voltage level of each connection node in a first protecting unit in accordance with various embodiments, FIG. 5B is a view illustrating a voltage level of each connection node in a second protecting unit in accordance with various embodiments and FIG. 6 is a circuit diagram illustrating a parasitic capacitance of the ESD protection circuit in FIG. 4.

Referring to FIG. 4, the ESD protection circuit 100 may include a first protecting unit 110 and a second protecting unit 120.

The first protecting unit 110 may be connected between the pad P and a first power voltage terminal V1T. The first protecting unit 110 may include n numbers of diodes D11˜D1n serially connected with each other (n is a natural number of no less than 2). Each of the diodes D11˜D1n may include an anode and a cathode. When a difference between a voltage applied from the pad P (hereinafter, referred to as a pad voltage Vp) and a voltage of the first power voltage terminal V1T (hereinafter, referred to as a first power voltage) is greater than a first set value, the diodes D11˜D1n of the first protecting unit 110 are turned-on. In one embodiment, the diodes D11˜D1n of the first protecting unit 110 may be connected from the pad P toward the first power voltage terminal V1T in a backward direction permitting charge flow under a positive bias. For example, the anode of the first diode D11 in the first protecting unit 110 may be connected to the pad P. The cathode of the first diode D11 may be connected to the anode of the second diode D12.

The second protecting unit 120 may be connected between the pad P and a second power voltage terminal V2T. The second protecting unit 120 may include n numbers of diodes D21˜D2m serially connected with each other. Each of the diodes D21˜D2n may include an anode and a cathode. When a difference between the pad voltage Vp and the second power voltage is less than a second set value, the diodes D21˜D2m of the second protecting unit 120 are turned-on. In one embodiment, the diodes D21˜D2m of the second protecting unit 120 may be connected from the second power voltage terminal V2T toward the pad P in a forward direction permitting charge flow under a negative bias. For example, the cathode of the second diode D21 in the second protecting unit 120 may be connected to the pad P. The anode of the second diode D21 may be connected to the cathode of the second diode D22.

In one example, the numbers of the diodes in the first protecting unit 110 may be substantially equal to or different from numbers of the diodes of the second protecting unit 120. In order to more easily generate a parasitic transistor path for discharging the static electricity, the numbers of the diodes D11˜D1n in the first protecting unit 110 may be greater than the numbers of the diodes D21˜D2m in the second protecting unit 120.

In one embodiment, the first set value may be greater than a sum of threshold voltages of the diodes D11˜D1n in the first protecting unit 110. In another embodiment, the second set value may be greater than a sum of the threshold voltages of the diodes D21˜D2m in the second protecting unit 120.

In one embodiment, when the normal I/O signal is received as the pad voltage Vp through the pad P, the diodes D11˜D1n of the first protecting unit 110 and the diodes D21˜D2m of the second protecting unit 120 may not be turned-on and the normal I/O signal passes to the control circuit CC connected and/or the memory cell array MCA. In another embodiment, the diodes D11˜D1n of the first protecting unit 110 and the diodes D21˜D2m of the second protecting unit 120 may be physically maintained in the serial state.

As shown in FIG. 5A, the n numbers of the diodes D11˜D1n of the first protecting unit 110 may have a same threshold voltage and a same impedance. Accordingly, sequentially increased voltages may be provided to first to nth node nd11˜nd1n so as to maintain the serial connection state of the diodes D11˜D1n of the first protecting unit 110 so that, in the event of static electricity, the first protection circuit will turn on more rapidly than if the sequentially increased voltages were not present. For example, the sequentially increased voltages may be provided in accordance with a voltage distribution rule. Particularly, a voltage corresponding to a value obtained by dividing a difference (V1-Vp) between a first power voltage V1 and the pad voltage Vp by n (the number of diodes in the first protecting unit 110) may be provided to the first node nd11. A voltage corresponding to a value obtained by multiplying the voltage difference (V1−Vp) between the first power voltage V1 and the pad voltage Vp by (n−1)/n may be provided to the nth node nd1n. A voltage difference between the anode and the cathode in each of the diodes D11˜D1n may be lower than the threshold voltage of the diodes D11˜D1n. For example, a voltage difference between the first node nd11 and the second node nd12 in the first protecting unit 110 may be lower than the threshold voltage of the first diode D11. A reference numeral V1s may be referred to as distribution voltages applied to the nodes nd11˜nd1n of the first protecting unit 110.

In the second protecting unit 120, as illustrated in FIG. 5B, in order to serially connect the diodes D21˜D2m before the inflow of the static electricity, a voltage obtained by multiplying a voltage difference (Vp−V2) between the pad voltage Vp and the second power voltage V2 by (m−1)/m may be applied to the first node nd21 of the second protecting unit 120. A voltage obtained by dividing the voltage difference (Vp−V2) between the pad voltage Vp and the second voltage V2 by m (the number of diodes in the second protecting unit 120) may be applied to the mth node nd2m. A voltage difference between the anode and the cathode in each of the diodes D21˜D2m may be lower than the threshold voltage of the diodes D21˜D2m. For example, a voltage difference between the first node nd21 and the second node nd22 in the second protecting unit 120 may be lower than the threshold voltage of the first diode D21. A reference numeral V2s may be referred to as distribution voltages applied to the nodes nd21˜nd2m of the second protecting unit 120, which (similar to the sequentially increased voltages in the first protecting unit 110) make possible a more rapid turn-on of the second protecting unit 120 than if the distribution voltages were not present.

When the ESD protection circuit 100 does not perform the static electricity discharge operation, as shown in FIG. 6, the diodes D11˜D1n and D21˜D2m of the ESD protection circuit 100 may be represented by a plurality of parasitic capacitors C11˜C1n and C21˜C2m. That is, because the distribution voltages V1s and V2s having different levels are inputted through the connection nodes nd11˜nd1n and nd21˜nd2m−1 of the parasitic capacitors C11˜C1n and C21˜C2m, the parasitic capacitors C11˜C1n and C21˜C2m may be formed between the nodes. When the capacitors are serially connected with each other compared to a parallel connection, the capacitors have a lower effective capacitance.

Therefore, the first protecting unit 110 and the second protecting unit 120 in the ESD protection circuit 100 may include the plurality of the diodes. Thus, when the static electricity is inputted, the static electricity can be effectively discharged. In contrast, when the static electricity is not inputted, the effect of the parasitic capacitance may be reduced.

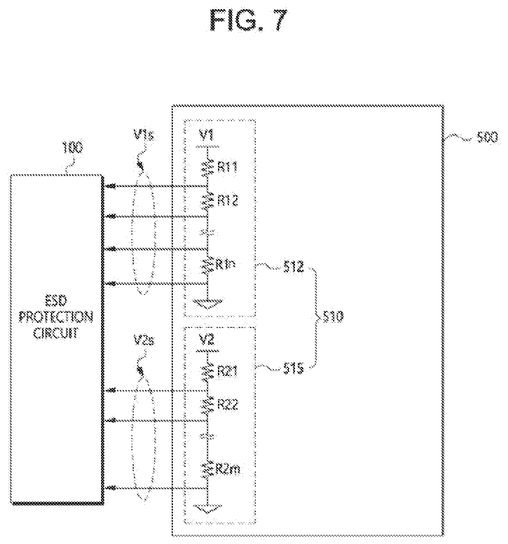

FIG. 7 is a circuit diagram illustrating a voltage distribution circuit of a semiconductor integrated circuit device in accordance with various embodiments.

Referring to FIG. 7, a voltage distribution circuit 510 may be arranged in the internal circuit 500. The voltage distribution circuit 510 may include a first distribution voltage generator 512 and a second distribution voltage generator 515.

The first distribution voltage generator 512 may include a plurality of resistances R11˜R1n serially connected between the first voltage terminal V1T and a ground terminal. Voltages generated from connection nodes of the resistances R11˜R1n may be used as the distribution voltages V1s (i.e., the sequentially increased voltages) of the first protecting unit 110.

The second distribution voltage generator 515 may include a plurality of resistances R21˜R2m serially connected between the second voltage terminal V2T and the ground terminal. Voltages generated from connection nodes of the resistances R21˜R2m may be used as the distribution voltages V2s of the second protecting unit 120.

As mentioned above, when the normal pad voltage Vp is received from the pad P, the ESD protection circuit 100 is not driven. In this case, the pad voltage Vp is transmitted to the internal circuit 500 to perform operations of the internal circuit 500.

In contrast, when the static electricity is inputted through the pad P, the ESD protection circuit 100 is driven so that the static electricity on the pad is conducted away from the internal circuit 500. Thus, almost all of the operations of the internal circuit 500 may be stopped so that the first and second distribution voltages V1s and V2s from the voltage distribution circuit 510 may not be outputted. Therefore, when the static electricity is inputted into the pad P, the artificial first and second distribution voltages V1s and V2s normally provided by the voltage distribution circuit 510 may not be provided to the connection nodes nd11˜nd1n and nd21˜nd2m of the first and second protecting units 110 and 120. In contrast, the voltages based on the pad voltage Vp including the static electricity may be divided across the connection nodes nd11˜nd1n and nd21˜nd2m of the first and second protecting units 110 and 120 serving to activate the first and second protecting units 110 and 120.

Further, in various embodiments, the distribution voltages V1s and V2s may be applied to the connection nodes nd11˜nd2n and nd21˜nd2m. Alternatively, distribution voltages V1s and V2s may be provided to the connection nodes nd11˜nd1n−1 and nd21˜nd2m−1 by the difference between the pad voltage Vp and the first power voltage and the difference between the pad voltage Vp and the second power voltage.

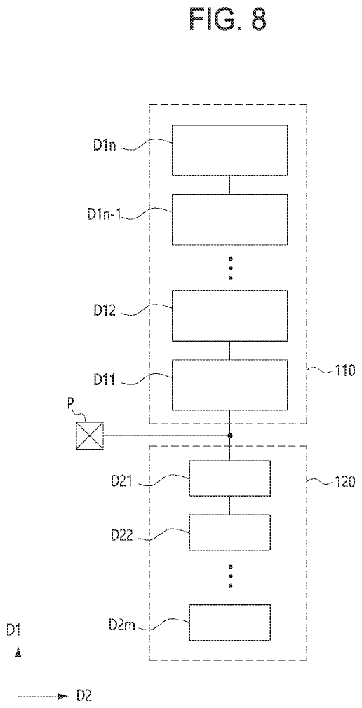

FIG. 8 is a plan view illustrating an ESD protection circuit in accordance with various embodiments.

Referring to FIG. 8, the diodes D11˜D1n and D21˜D2m in the first and second protecting units 110 and 120 of the ESD protection circuit 100 may be arranged serially in a first direction D1.

In one embodiment, the first diode D11 of the first protecting unit 110 connected to the pad P and the first diode D21 of the second protecting unit 120 connected to the pad P may face each other. By having the first diode D11 of the first protecting unit 110 face the first diode D21 of the second diode 120, with each having opposite main carriers, a parasitic npn path may exist between the first diode D11 of the first protecting unit 110 and the first diode D21 of the second protecting unit D21 when the static electricity is inputted.

A substantial amount of carriers may accumulate in the parasitic npn path even prior to static electricity occurrence, and thereby reduce the on-resistance of the ESD protection circuit 100 when static electricity is inputted.

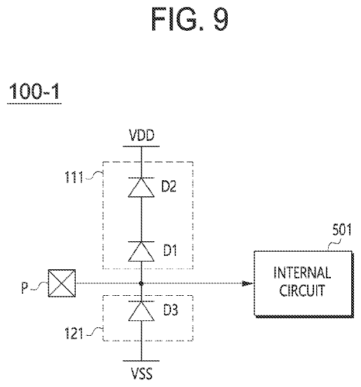

FIG. 9 is a circuit diagram illustrating an ESD protection circuit in accordance with various embodiments.

Referring to FIG. 9, an ESD protection circuit 100-1 may be connected between an I/O pad P and an internal circuit 501. The ESD protection circuit 100-1 may include a first protecting unit 111 and a second protecting unit 121.

The first protecting unit 111 may include first and second diodes D1 and D2 serially connected between a VDD voltage terminal and the I/O pad P. In order to operate the first and second diodes D1 and D2, when the voltage including positive static electricity is inputted into the I/O pad P, the first and second diodes D1 and D2 are connected between the I/O pad P and the VDD voltage terminal in the backward direction.

An internal voltage Va may be provided to a connection node ND1 between the first diode D1 and the second diode D2. The internal voltage Va may be any one of voltages generated from the internal circuit 501. In one embodiment, the internal voltage Va may be generated from a voltage distribution circuit of the internal circuit 501, but the present invention is not limited thereto. When the normal pad voltage Vp is received from the I/O pad P, for example, the internal voltage Va may be a value obtained by dividing a difference between the VDD voltage and the pad voltage Vp by two corresponding to numbers of the diodes of the first protecting unit 111. A difference between the internal voltage Va and the pad voltage Vp may be lower than a threshold voltage of the first diode D1. A difference between the VDD voltage and the internal voltage Va may be lower than a threshold voltage of the second diode D2. When the static electricity is not inputted, the first and second diodes D1 and D2 may not be turned-on. Parasitic capacitances generated by the first and second didoes D1 and D2 will be in a physically serial connection state and have an effective lower capacitance.

Further, in one embodiment, the internal voltage V1 may not be additionally provided from the internal circuit 501. In this embodiment, the internal voltage Va may exist as a result of the difference between the pad voltage Vp and the VDD voltage and as a result of the difference between the pad voltage Vp and the VSS voltage.

The second protecting unit 121 may include a third diode D3 connected between the I/O pad P and the VSS terminal. In one embodiment, the number of the didoes in the second protecting unit 121 may be less than the number of the diodes in the first protecting unit 111. The third diode D3 of the second protecting unit 121 may be connected in the forward direction so that the third diode D3 may be driven in the static electricity ESD event.

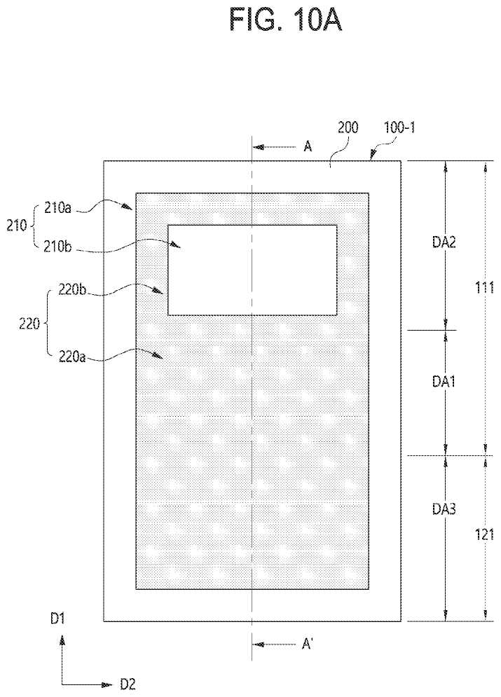

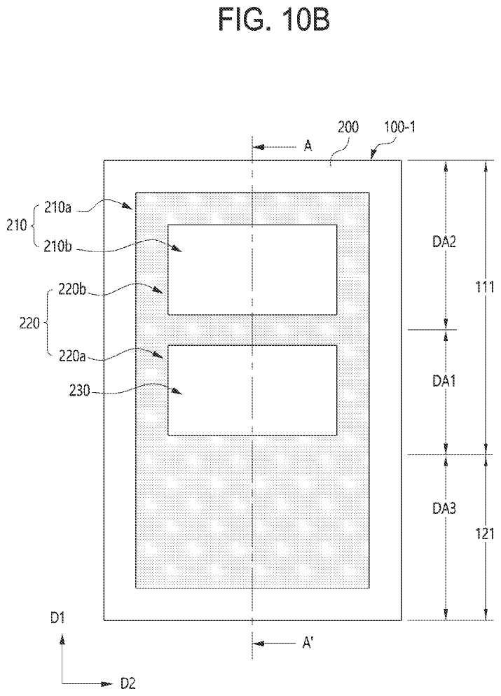

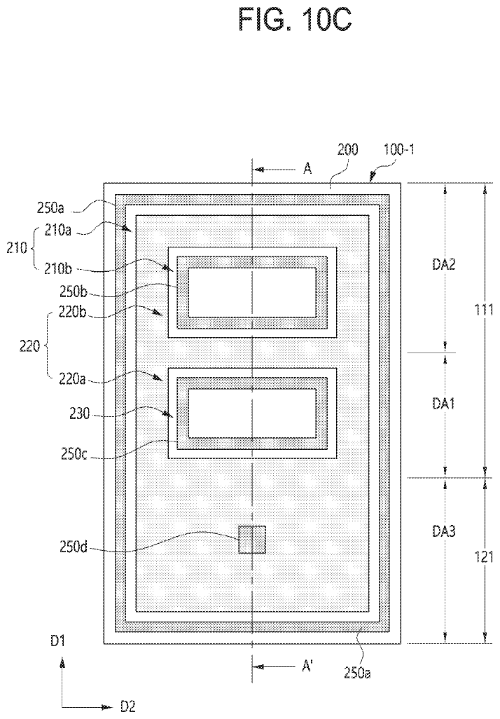

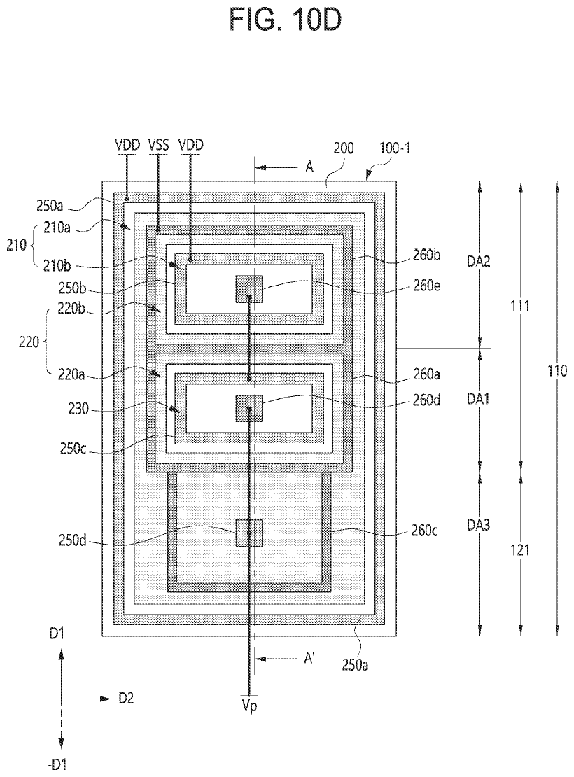

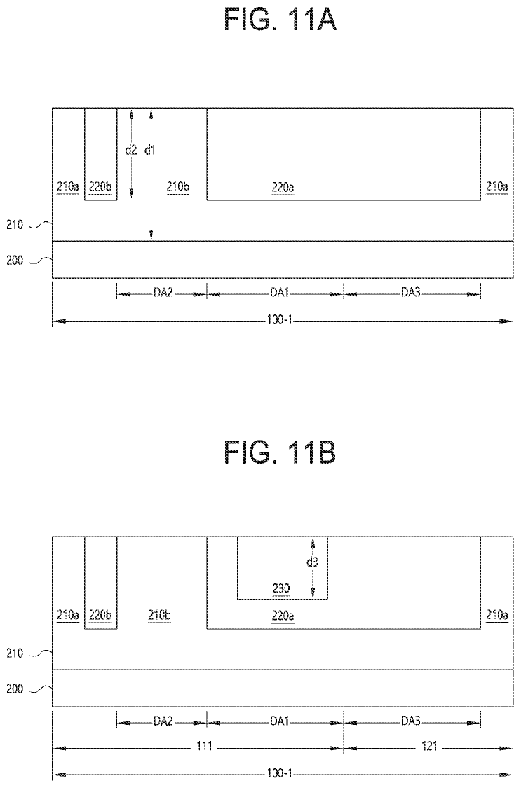

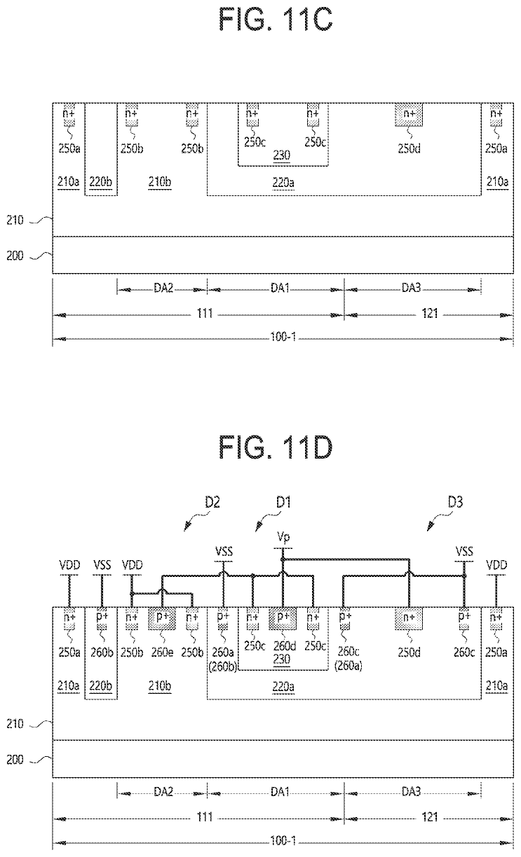

FIGS. 10A to 10D are plan views illustrating a method of manufacturing the ESD protection circuit as shown in in FIG. 9 and FIGS. 11A to 11D are cross-sectional views taken along a line A-A′ in FIGS. 10A to 10D.

Referring to FIGS. 9, 10A and 11A, a first N-well 210 may be formed in a region of a semiconductor substrate 200. An ESD protection circuit 100-1 may also be formed in the same region. The first N-well 210 may include a deep N-well having a first depth d1 from a surface of the semiconductor substrate 200.

A P-well 220 may be formed in the first N-well 210. The P-well 220 may have a second depth d2 shallower than the first depth d1. In one embodiment, the P-well 220 may include a first portion 220a in which a first diode region DA1 of the first protecting unit 111 and a third diode region DA3 of the second protecting unit 121 may be formed later. For example, the first portion 220a may have a plate shape.

Further, the P-well 220 may include a second portion 220b configured to expose a second N-well 210b, which may make contact with the first portion 220a, in the second diode region DA2. In one example, the second portion 220b may have a frame shape. In order to apply a voltage to the first N-well 210, the first and second portions 220a and 220b of the P-well 220 may be formed to expose an edge region 210a of the first N-well 210.

Referring to FIGS. 9, 10B and 11B, a second N-well 230 may be formed in the P-well 220 corresponding to the first diode region DA1. The second N-well 230 may have a third depth d3. The second N-well 230 may correspond to a cathode region of the first diode D1. An impurity concentration of the second N-well 230 may be set to provide the first and second diodes D1 and D2 with a same threshold voltage. In one example, in order to rapidly generate a parasitic path in the first diode D1, the impurity concentration of the second N-well 230 may be higher than an impurity concentration of the first N-well 210. Further, the depth of the second N-well 230 may be decreased in proportion to increasing the impurity concentration of the second N-well 230. The second N-well 230 may be spaced apart from the first N-well 210. The P-well 220 may be positioned between the second N-well 230 and the first N-well 210. Because the second N-well 230 may be formed in the P-well 220, the second N-well 230 may be referred to as a pocket N-well.

Referring to FIGS. 9, 10C and 11C, N-type impurities having a high concentration may be implanted into the edge region 210a of the first N-well, into the first N-well 210b corresponding to the second diode region DA2, into a portion of the second N-well 230, and into the P-well 220a corresponding to the third diode region DA3 to form respectively N-type impurity regions 250a, 250b, 250c and 250d having a high concentration. The high impurity concentration may be a dopant concentration higher than a dopant concentration of the first N-well.

The reference numeral 250a may correspond to a first N-well contact region formed at the edge region of the first N-well 210 to transmit a power voltage to the first N-well 210. The first N-well contact region 250a may make contact with a wiring configured to transmit the power voltage.

The reference numeral 250b may correspond to a first N-well contact region configured to apply the power voltage to the first N-well 210b corresponding to the second diode region DA2. The first N-well contact region 250b may receive a voltage applied to the cathode of the second diode D2. The first N-well contact region 250b may be formed along the edge of the first N-well 210b.

The reference numeral 250c may be a second N-well contact region formed in the second N-well 230. That is, the second N-well contact region 250c may make contact with a wiring having a voltage, such as for example the internal voltage detailed above which can be applied to the cathode of the first diode D1. The second N-well contact region 250c may be formed along the edge of the second N-well 230.

The reference numeral 250d may correspond to a cathode region of the third diode D3 formed in the P-well 220a positioned in the third diode region DA3.

Referring to FIGS. 9, 10D and 11D, P-type impurities having a high concentration may be implanted into portions of the P-well 220, into the second N-well 230, and into the first N-well 210b to form respectively P-type impurities 260a, 260b, 260c, 260d and 260e having a high impurity concentration.

The reference numeral 260a may be a first P-well contact region formed in the P-well 220a corresponding to an outer edge of the second N-well 230. The first P-well contact region 260a may have a frame shape configured to define the first diode region DA1.

The reference numeral 260b may be a second P-well contact region formed in the P-well 220 at an outskirt of the first N-well 210b. The second P-well contact region 260b may have a frame shape configured to define the second diode region DA2. The P-type impurity region (between the second N-well 230 and the first N-well 210b) may be provided as the first P-well contact region 260a and the second P-well contact region 260b.

The reference numeral 260c may be a third P-well contact region formed in the P-well 220 corresponding to the third diode DA3. A size of the third diode region DA3 may be defined by the third P-well contact region 260c. The third P-well contact region 260c may have a frame shape configured to surround the cathode 250d of the third diode D3. The third P-well contact region 260c may be formed in a reverse first direction (−D1) with respect to the P-well contact region 260a so that the third P-well contact region 260c and the first P-well contact region 260a face each other. In one embodiment, a facing region between the third P-well contact region 260c and the P-well contact region 260a is a shared common region connecting the first diode region DA1 to the third diode region DA3, as shown in FIG. 10D.

The reference numeral 260d is an anode region of the first diode D1 formed in the second N-well 230.

The reference numeral 260e is an anode region of the second diode D2 formed in the first N-well 210b.

The anode region 260d of the first diode D1 and the cathode region 250d of the third diode D3 are electrically connected to the I/O pad P through a wiring to receive the pad voltage Vp.

The third N-well contact region 250c and the anode region 260e of the second diode D2 may receive the internal voltage Va provided from the internal circuit 501. Thus, the cathode region of the first diode D1 and the anode region 260e of the second diode D2 may commonly receive a same voltage.

The first N-well contact region 250a and the second N-well contact region 250b may be electrically connected with each other to receive the VDD voltage. The first to third P-well contact regions 260a, 260b and 260c may be electrically connected with each other to receive the VSS voltage.

In order to serially connect the first and second diodes D1 and D2 in the first protecting unit 111 of the ESD protection circuit 100-1 when the static electricity is not inputted, the internal voltage Va may be applied to the cathode of the first diode D1 and the anode of the second diode D2. Thus, the parasitic capacitance of the ESD protection circuit 100-1 may be reduced as the second diodes D2 conducts charge to the VDD terminal.

Further, in order to prevent the on-resistance of the ESD protection circuit 100-1 from being increased, the third diode D3 in the second protecting unit 121 discharging the negative static electricity and the first diode D1 in the first protecting unit 111 discharging the positive static electricity may be serially arranged. Particularly, the third diode D3 and the first diode D1 discharging the different types of static electricity may be formed in one P-well 220 so that the parasitic npn path may be formed between the first to third diodes D1˜D3 of the ESD protection circuit 100-1 to decrease the on-resistance for discharging positive static electricity.

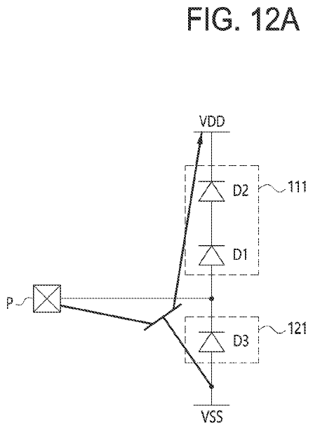

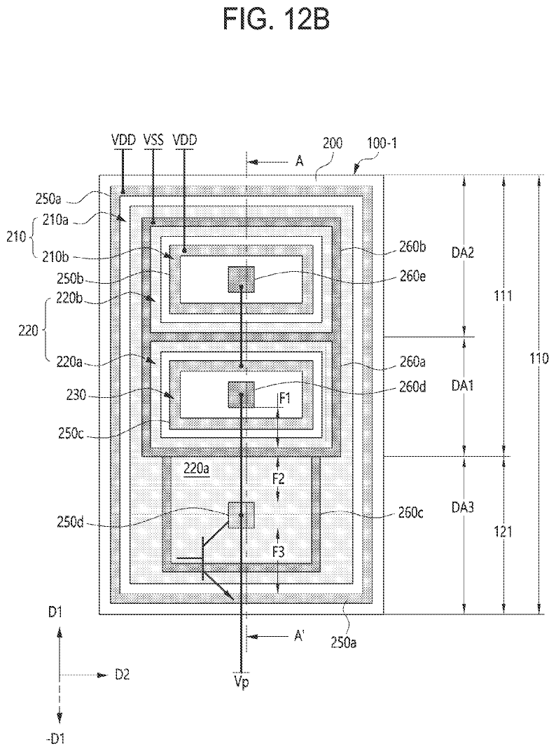

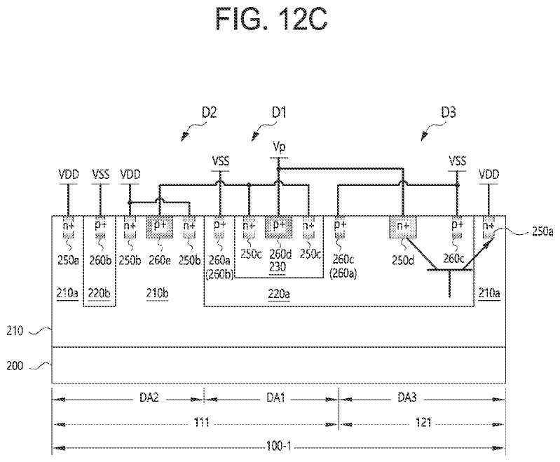

FIG. 12A is a circuit diagram illustrating a parasitic path of an ESD protection circuit in accordance with various embodiments, FIG. 12B is a plan view illustrating a parasitic path of an ESD protection circuit in accordance with these embodiments and FIG. 12C is a cross-sectional view illustrating a parasitic path of an ESD protection circuit in accordance with these embodiments.

Referring to FIGS. 12A to 12C, the first diode D1 and the third diode D3 may be formed in one P-well 220 and face each other. Thus, in one embodiment, when the static electricity is inputted from the pad P, there exists a parasitic npn BJT between a) the cathode n+ region 250d of the third diode D3, which may be electrically connected to the pad P, b) the first portion 220a of the P-well 220 (a p region) in which the first diode D1 and the third diode D3 may be integrated and c) the first N-well contact region 250a (a n+ region) nearest to the first portion 220a. The existence of the parasitic npn BJT improves the on-resistance of the ESD protection circuit 100-1.

Further, the first portion 220a of the P-well 220 corresponding to a base of the parasitic BIT may be formed in the first N-well 210 in a retrograde shape. The second N-well 230 corresponding to an emitter of the parasitic BIT may be formed in the first portion 220a of the P-well 220 in a pocket shape within the P-well 220. Thus, a substantial amount of holes may be accumulated in the first portion 220a of the P-well 200 in the ESD event. The accumulated holes may increase a base potential of the parasitic BIT so that the parasitic BIT may be rapidly turned-on to improve the on-resistance.

Furthermore, a distance between the first diode D1 and the third diode D3 connected to the pad P may be controlled so that the ESD protection circuit 100-1 may activate the generation of the parasitic MT, i.e., the generation of a parasitic conductive path for discharging the static electricity.

In one embodiment, when a distance F1 (as shown in FIG. 12B) between the anode region 260d of the first diode D1 and the third P-well contact region 260c adjacent to the anode region 260 is decreased, the parasitic pnp path may be more rapidly generated between the anode region 260d of the first diode D1, the third N-well contact region 250c and the third P-well contact region 260c to promote the turning on of the parasitic npn BIT.

In another embodiment, a distance F2 (as shown in FIG. 12B) between the third P-well contact region 260c and the cathode region 250d of the third diode D3 commonly used with the P-well contact region 260a is provided with a uniform gap where holes can accumulate without any influence of a latch-up.

In another embodiment, when a distance F3 (as shown in FIG. 12B) between the cathode region 250a of the third diode D3 and the first N-well contact region 260a adjacent to the third diode region DA3 is decreased, the parasitic npn path may be more easily turned on. However, in this case, a threshold voltage of the ESD protection circuit 100-1 may be decreased. Thus, the distance F3 may be controlled based on the threshold voltage of the ESD protection circuit to compensate for the on-resistance.

The above described embodiments of the present invention is are intended to illustrate and not to limit the present invention. Various alternatives and equivalents are possible. The invention is not limited by the embodiments described herein. Nor is the invention limited to any specific type of semiconductor device. In view of the disclosure, other additions, subtractions, or modifications are recognizable to those skilled in the art.

What is claimed is:

1. A semiconductor integrated circuit device comprising:
a first protecting unit including first to nth backward diodes connected in series and disposed between a pad and a first power line, wherein n is a natural number; and
a second protecting unit including at least one forward diode connected between the pad and the second power line,
wherein
the first to nth backward diodes include a first backward diode connected to the pad,
the at least one forward diode includes a first forward diode connected to the pad, and
the first backward diode and the first forward diode are integrated in one conductive well and face each other with a shared common region.

2. The semiconductor integrated circuit device of claim 1, wherein the at least one forward diode of the second protecting unit comprises first to mth forward diodes connected in series and m is a natural number equal to or less than n.

3. The semiconductor integrated circuit device of claim 1, wherein each of the first to nth backward diodes includes a cathode and an anode, the cathode includes an N-well and the anode includes a P-type impurity region having a high dopant concentration in the N-well.

4. The semiconductor integrated circuit device of claim 3 wherein the forward diode comprises an anode and a cathode, and the anode of the forward diode includes a P-well and the cathode of the forward diode includes an N-type impurity region having a high dopant concentration in the P-well.

5. The semiconductor integrated circuit device of claim 4, wherein the N-well corresponding to the cathode of the first backward diode is formed in the P-well corresponding to the anode of the forward diode.

6. The semiconductor integrated circuit device of claim 4, wherein the N-well corresponding to the cathode of the first backward diode has a depth smaller than a depth of the P-well corresponding to the anode of the forward diode.

7. The semiconductor integrated circuit device of claim 4, wherein an impurity concentration of the cathode of the first backward diode is higher than impurity concentrations of the cathodes of the second to nth backward diodes.

8. The semiconductor integrated circuit device of claim 5, wherein a depth of the N-well corresponding to the cathode of the first backward diode is smaller than depths of the N-wells corresponding to cathodes of the second to nth backward diodes.

9. A semiconductor integrated circuit device comprising:
a first forward diode electrically connected between a pad and a power voltage terminal and formed in a first N-well with a first depth, the first forward diode including anode and a cathode, wherein the anode of the first forward diode includes a P-well having a second depth, the cathode of the first forward diode includes an N-type impurity region having a high dopant concentration formed in the P-well, and the N-type impurity region is electrically connected with the pad; and
a first backward diode electrically connected between the pad and a ground voltage terminal and formed in the P-well, the first backward diode including a cathode and an anode, wherein the cathode of the first backward diode includes a second N-well with a third depth smaller than the second depth, the anode of the first backward diode includes a P-type impurity region having a high dopant concentration formed in the second N-well, and the P-type impurity region is electrically connected with the pad,
wherein a parasitic bipolar junction transistor (BJT) exists between the first N-well, the P-well and the second N-well when a voltage including a static electricity is inputted from the pad.

10. The semiconductor integrated circuit device of claim 9, further comprising a second backward diode including an anode and a cathode,
wherein the anode of the second backward diode includes the first N-well and the cathode includes a P-type impurity region having a high dopant concentration formed in the first N-well, and
wherein the anode of the second backward diode is connected to the cathode of the first backward diode.

11. The semiconductor integrated circuit device of claim 9, wherein the second N-well has an impurity concentration higher than an impurity concentration of the first N-well.

12. The semiconductor integrated circuit device of claim 9, wherein the first depth is substantially equal to or greater than the second depth.

13. A memory system comprising:
a semiconductor substrate;
an input/out (I/O) pad;
a first voltage terminal;
a second voltage terminal;
a memory cell array;
a control circuit a) in communication with the I/O pad and the memory cell array, b) configured to control a selected memory cell of the memory cell array and c) having electrostatic discharge (ESD) protection circuitry disposed on the semiconductor substrate,
wherein the ESD protection circuitry comprises:
first to nth backward diodes formed in the semiconductor substrate and connected in series between the input/out pad and a first power line, wherein n is a natural number,
first to mth forward diodes formed in the semiconductor substrate and connected in series and connected to the I/O pad and a second power line, where m is a natural number equal to or less than n, and
a first backward diode of the first to nth backward diodes is connected to a first forward diode of the first to mth forward diodes, and
wherein positive static electricity on the I/O pad is discharged by the first to nth backward diodes to the first voltage terminal,
negative static electricity on the I/O pad is discharged by the first to mth forward diodes to the second voltage terminal, and
a parasitic bipolar junction transistor (BJT) exists in the semiconductor substrate between the I/O pad, the first voltage terminal, and the second voltage terminal to assist in discharging the negative and positive static electricity from the I/O pad.

14. The memory system of claim 13, wherein
the first to nth backward diodes include a first backward diode connected to the I/O pad,
the first to mth forward diodes include a first forward diode connected to the I/O pad, and
the first backward diode and the first forward diode are integrated in one conductive well and face each other with a shared common region.

15. The memory system of claim 14, wherein the first backward diode and the first forward diode are integrated in one conductive well.
